(19) United States
(12) Patent Application Publication
(10) Pub. No.: US 2007/0241834 A1
(43) Pub. Date: Oct. 18, 2007

(54) Frequency fine- tuning circuit and voltage-controlled oscillator including the same

(76) Inventor: Kun-Seok Lee, Seoul (KR)

Correspondence Address: LAW OFFICE OF MONICA H CHOI, P O BOX 3424, DUBLIN, OH, 430160204, US

(21) Appl. No.: 11/728,488

(22) Filed: Mar. 26, 2007

(30) Foreign Application Priority Data
Mar. 28, 2006 (KR) 2006-27706

(51) Int. Cl. H03B 5/12

(52) U.S. Cl. 331/177 V

(57) ABSTRACT

A frequency fine-tuning circuit includes first and second varactors. The first varactor is coupled between a tuning node with a first tuning voltage applied thereon and a first node with a second tuning voltage applied thereon. The second varactor is coupled between the first node and a second node with a bias voltage applied thereon. The second tuning voltage is in a range between the first tuning voltage and the bias voltage such as an average of the first tuning voltage and the bias voltage for increasing linearity of the frequency fine-tuning circuit.

This application claims priority under 35 USC §119 to Korean Patent Application No. 2006-27706, filed on Mar. 28, 2006 in the Korean Intellectual Property Office, the disclosure of which is incorporated herein in its entirety by reference.

### BACKGROUND OF THE INVENTION

1. Field of the Invention

The present invention relates generally to tuned oscillators, and more particularly to a frequency fine-tuning circuit with enhanced linearity and to a voltage-controlled oscillator (VCO) including the frequency fine-tuning circuit.

2. Description of the Related Art

With widespread use, demand for high quality mobile communication devices is ever increasing. For instance, a voltage-controlled oscillator (VCO) is one of the devices used in a mobile communication device, such as for a wide-band receiver. In addition, the performance of the VCO significantly affects the quality of the mobile communication.

A VCO includes an active circuit, an LC (inductor capacitor) tank for frequency oscillation, and a tuning circuit for tuning an oscillation frequency. The tuning circuit includes a fine-tuning circuit and/or a coarse-tuning circuit.

Moreover, the tuning circuit is implemented in a variety of forms such as by including a diode having a p+/n-well junction structure with a variable capacitance. However, such a conventional tuning circuit may not have a high quality factor (that is, Q value) due to a relatively high capacitance of the diode. In that case, the performance of the tuning circuit using the diode may be degraded. To address such a problem, an accumulation metal-oxide semiconductor (AMOS) varactor is used in a tuning circuit.

FIG. 1 shows a circuit diagram of a conventional tuning circuit using a diode with a p+/n-well junction structure. FIG. 2 shows a circuit diagram of a conventional tuning circuit using an AMOS varactor. FIG. 3 shows a tuning characteristic of the conventional tuning circuit of FIG. 1, and FIG. 4 shows a tuning characteristic of the conventional tuning circuit of FIG. 2.

Referring to FIG. 1, a tuning voltage Vtune is applied on a p+ terminal of the diode, and a bias voltage Vdc is applied on an n-well junction terminal of the diode via a resistor. A blocking capacitor is coupled between an oscillating node and the n-well junction terminal of the diode.

Referring to FIG. 2, a tuning voltage Vtune is applied on a coupled source and drain terminal of the AMOS varactor, and a bias voltage Vdc is applied on a gate terminal of the AMOS varactor via a resistor. A blocking capacitor is coupled between an oscillating node and the gate terminal of the AMOS varactor.

Referring to FIG. 3, the diode varactor of FIG. 1 has a tuning characteristic with a gain change of a VCO being smooth and with a wide tuning range. However, a lowest capacitance corresponding to an upper tuning voltage at point B is much greater than a corresponding capacitance at a point B′ in FIG. 4 for the AMOS varactor. Such large capacitance lowers the oscillating frequency of the VCO, and a large tuning voltage is required for increasing the oscillating frequency of the VCO. In addition, such a large capacitance increases the size of the diode varactor of FIG. 1 compared to the AMOS varactor of FIG. 2.

Referring to FIG. 4, the AMOS varactor has a low capacitance of about 140 fF at point B′ such that the AMOS varactor is amenable for a high-speed VCO. In addition, the AMOS varactor has a smaller size compared to the diode varactor. However, a range of the tuning voltage for the AMOS varactor is very narrow (about 1.0V˜2.0V with respect to a capacitance range of about 450 fF between points A′ and B′).

Thus, a gain change of a VCO having the AMOS varactor is very large such that the AMOS varactor disadvantageously has poor linearity. However, a wide tuning range is crucial for a wideband code division multiple access (W-CDMA) transmission mode because a signal bandwidth is very wide in the W-CDMA transmission mode.

### SUMMARY OF THE INVENTION

Accordingly, a frequency fine-tuning circuit uses multiple varactors such as multiple AMOS varactors for enhanced linearity.

A frequency fine-tuning circuit according to an aspect of the present invention includes first and second varactors. The first varactor is coupled between a tuning node with a first tuning voltage applied thereon and a first node with a second tuning voltage applied thereon. The second varactor is coupled between the first node and a second node with a bias voltage applied thereon. The second tuning voltage is in a range between the first tuning voltage and the bias voltage.

For example, the second tuning voltage is less than the bias voltage and greater than the first tuning voltage. The second tuning voltage is an average of the first tuning voltage and the bias voltage in an example embodiment of the present invention.

In a further embodiment of the present invention, the frequency fine-tuning circuit includes a blocking capacitor coupled between the second node and an -oscillating node. The blocking capacitor prevents DC noise from being transferred to the second node. The blocking capacitor is a metal-insulator-metal (MIM) capacitor in an example embodiment of the present invention.

In an example embodiment of the present invention, the first varactor is a first AMOS (accumulation metal-oxide semiconductor) varactor having a first coupled source and drain terminal connected to the tuning node and having a first gate terminal connected to the first node. The second varactor is a second AMOS (accumulation metal-oxide semiconductor) varactor having a second coupled source and drain terminal connected to the first node and having a second gate terminal connected to the second node.

In another embodiment of the present invention, the first tuning voltage is in a range of a ground voltage to the bias voltage.

In a further embodiment of the present invention, the frequency fine-tuning circuit further includes a first resistor coupled between the first node and a third node having the second tuning voltage applied thereon. A second resistor is also coupled between the second node and a fourth node having the bias voltage applied thereon. In an example embodiment of the present invention, the resistances of the first and second resistors are substantially same.

In another embodiment of the present invention, the frequency fine-tuning circuit further includes a first division resistor coupled between the tuning node and the third node. A second division resistor is also coupled between the third node and the fourth node. In an example embodiment of the present invention, the resistances of the first and second division resistors are substantially same. In another example embodiment of the present invention, the first and second division resistors are implemented with turned-on diodes.

According to another aspect of the present invention, the frequency fine-tuning circuit includes at least one additional varactor coupled in series with the first and second varactors, with voltages at nodes between the varactors of the series varying between the tuning voltage and the bias voltage. In that case, a series of division resistors are coupled between the tuning node and a node having the bias voltage applied thereon. In addition, a respective one of the nodes between the varactors is coupled via a respective resistor to a respective one of a plurality of nodes between the division resistors.

According to another embodiment of the present invention, a voltage-controlled oscillator (VCO) includes an active circuit having first and second oscillating nodes, an inductor and a capacitor coupled in parallel between the first and second oscillating nodes, and a frequency fine-tuning circuit. The frequency fine-tuning circuit includes at least one varactor unit each coupled to a respective one of the first and second oscillating nodes. Each varactor unit includes a first varactor and a second varactor. The first varactor is coupled between a tuning node with a first tuning voltage applied thereon and a first node with a second tuning voltage applied thereon. The second varactor is coupled between the first node and a second node with a bias voltage applied thereon. The second tuning voltage is in a range between the first tuning voltage and the bias voltage, and the second node is coupled to the respective one of the first and second oscillating nodes.

In a further embodiment of the present invention, the at least one varactor includes first and second varactor units with the first varactor unit having the first and second varactors with the second node being coupled to the first oscillating node. In that case, the second varactor unit includes third and fourth varactors. The third varactor is coupled between the tuning node with the first tuning voltage applied thereon and a third node with a third tuning voltage applied thereon. The fourth varactor is coupled between the third node and a fourth node with the bias voltage applied thereon. The fourth tuning voltage is in a range between the first tuning voltage and the bias voltage, and the fourth node is coupled to the second oscillating node.

In this manner, the VCO with such a frequency fine-tuning circuit has smaller gain change with enhanced linearity of the frequency fine-tuning circuit. Such enhanced linearity is amenable for wide tuning range.

### BRIEF DESCRIPTION OF THE DRAWINGS

The above and other features and advantages of the present invention will become more apparent when described in detailed exemplary embodiments thereof with reference to the attached drawings in which:

FIG. 1 is a circuit diagram of a conventional tuning circuit using a diode with a p+/n-well junction structure;

FIG. 2 is a circuit diagram of a conventional tuning circuit using an AMOS varactor;

FIG. 3 shows a tuning characteristic of the conventional tuning circuit of FIG. 1;

FIG. 4 shows a tuning characteristic of the conventional tuning circuit of FIG. 2;

FIG. 5 shows a circuit diagram of a frequency fine-tuning circuit with enhanced linearity, according to an embodiment of the present invention;

FIG. 6 shows a circuit diagram for an example frequency fine-tuning circuit according to FIG. 5 with additional resistors for maintaining a tuning voltage, according to an embodiment of the present invention;

FIG. 7 shows a circuit diagram for an example frequency fine-tuning circuit according to FIG. 5 with additional diodes for maintaining a tuning voltage, according to an embodiment of the present invention;

FIG. 8 shows a graph illustrating a tuning characteristic of the frequency fine-tuning circuit of FIG. 5;

FIG. 9 is a circuit diagram of a frequency fine-tuning circuit with more numerous varactors than FIG. 5, according to another embodiment of the present invention;

FIG. 10 is a block diagram of a voltage-controlled oscillator (VCO) including a frequency fine-tuning circuit with enhanced linearity, according to an embodiment of the present invention;

FIG. 11 is a circuit diagram of an example frequency fine-tuning circuit in FIG. 10, according to an embodiment of the present invention; and

FIG. 12 is a circuit diagram of an example active circuit in FIG. 10, according to an embodiment of the present invention.

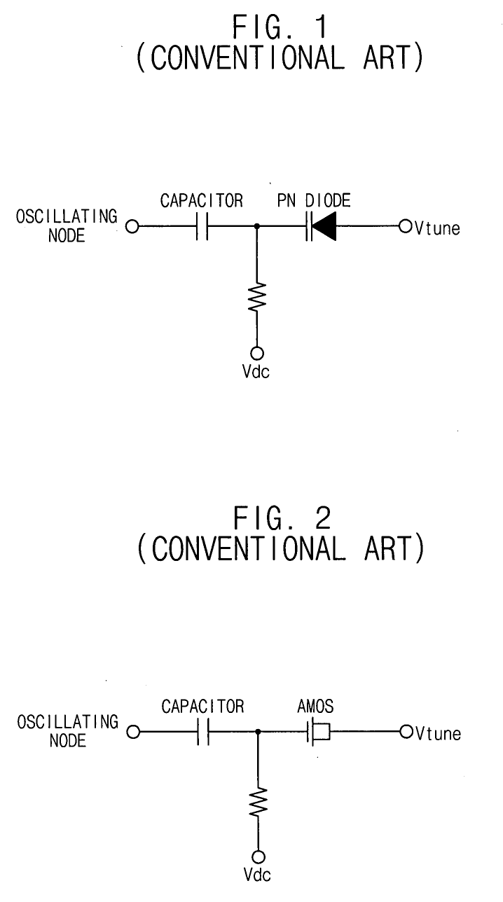

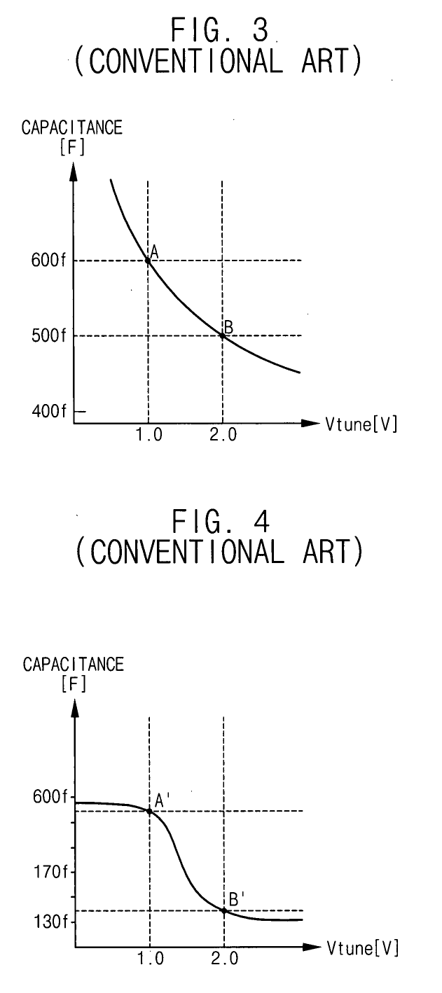

The figures referred to herein are drawn for clarity of illustration and are not necessarily drawn to scale. Elements having the same reference number in FIGS. 1, 2, 3, 4, 5, 6, 7, 8, 9, 10, 11, and 12 refer to elements having similar structure and/or function.

### DETAILED DESCRIPTION OF THE INVENTION

Embodiments of the present invention now will be described more fully with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

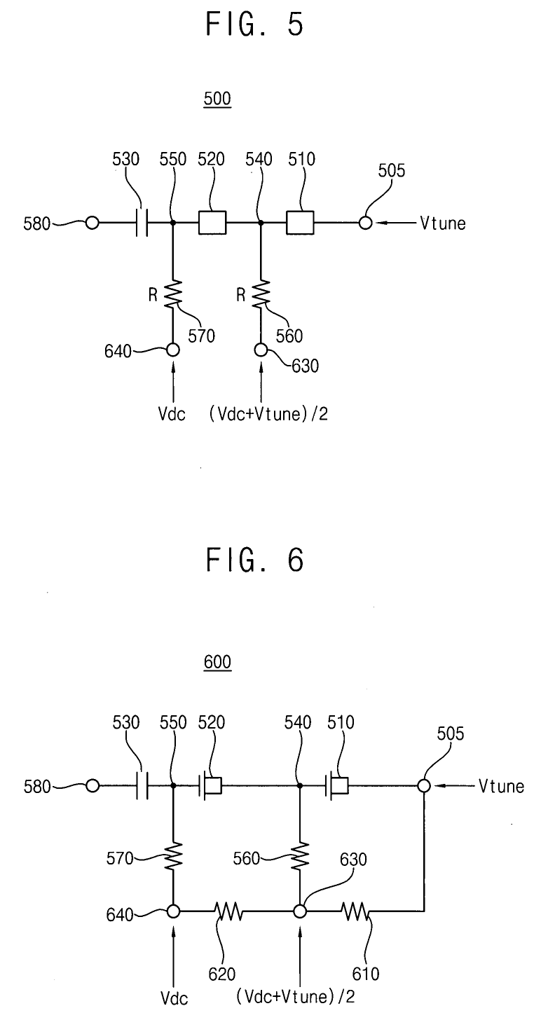

FIG. 5 shows a circuit diagram of a frequency fine-tuning circuit 500 according to an example embodiment of the present invention. Referring to FIG. 5, the frequency fine-tuning circuit 500 includes a tuning node 505, a first varactor 510, a second varactor 520, an oscillating node 580, a blocking capacitor 530, a first resistor 560, and a second resistor 570.

In one example embodiment of the present invention as illustrated in FIG. 6, each of the first and second varactors 510 and 520 is a respective accumulation metal-oxide semiconductor (AMOS) varactor. Each AMOS varactor has a coupled source and drain terminal and a gate terminal. The source and drain that are coupled together form the coupled source and drain terminal. The structure of an AMOS varactor individually is known to one of ordinary skill in the art. Further in an example embodiment of the present invention, the blocking capacitor 530 is a metal-insulator-metal (MIM) capacitor.

Referring to FIG. 5, a first terminal of the first varactor 510 (such as the coupled source and drain terminal of a first AMOS varactor in FIG. 6) is coupled to or may be the tuning node 505. A second terminal of the first varactor 510 (such as the gate terminal of the first AMOS varactor in FIG. 6) is coupled to a first terminal of the second varactor 520 (such as the coupled source and drain terminal of a second AMOS varactor in FIG. 6) at a first node 540.

A second terminal of the second varactor 520 (such as the gate terminal of the second AMOS varactor in FIG. 6) is coupled to the oscillating node 580 via the blocking capacitor 530. In FIG. 5, a first terminal of the blocking capacitor 530 is connected to the second terminal of the second varactor 520 at a second node 550. In that case, a second terminal of the blocking capacitor 530 may form the oscillating node 580. The first resistor 560 is coupled between the first node 540 and a third node 630. The second resistor 570 is coupled between the second node 550 and a fourth node 640. The resistances of the first and second resistors 560 and 570 are substantially same according to an example embodiment of the present invention.

A first tuning voltage (Vtune) is applied on the tuning node 505, and a bias voltage (Vdc) is applied on the fourth node and thus on the second node 550 through the second resistor 570. A second tuning voltage is applied on the third node 630 and thus on the first node 540 through the first resistor 560. In an example embodiment of the present invention, the resistances of the first and second resistors 560 and 570 are substantially the same (i.e., R).

The bias voltage Vdc is for DC biasing, and the second varactor 520 has a respective variable capacitance that is determined by the second tuning voltage. The first varactor 510 has a respective variable capacitance that is determined by the first tuning voltage and the second tuning voltage.

The second tuning voltage at the first node 540 is set to be in a range between the first tuning voltage Vtune and the bias voltage Vdc. For example, the second tuning voltage is less than the bias voltage Vdc and greater than the first tuning voltage Vtune. In one example embodiment of the present invention, the second tuning voltage is maintained at an average of the first tuning voltage and the bias voltage, (i.e., (Vtune+Vdc)/2).

In an embodiment of the present invention, the first tuning voltage is in a range of from a ground voltage to the bias voltage. Accordingly, the second tuning voltage is in a range of from a half of the bias voltage to the bias voltage, i.e., from (Vdc/2) to Vdc. The first capacitance of the first varactor 510 and the second tuning voltage change according to a change of the first tuning voltage. A second capacitance of the second varactor 520 changes according to the change of the second tuning voltage.

A total capacitance at the oscillating node 580 changes according to the changes of the first and second capacitances of the first and second varactors 510 and 520. An oscillating frequency of a voltage-controlled oscillator (VCO) including the frequency fine-tuning circuit 500 of FIG. 5 changes according to the total capacitance at the oscillating node 580.

The blocking capacitor 530 prevents DC noise from being transferred to the second node 550.

Because the second tuning voltage is maintained at the average of the first tuning voltage and the bias voltage, i.e., (Vtune+Vdc)/2, a tuning range and a linearity of the frequency fine-tuning circuit 500 are increased. FIG. 8 is a graph illustrating the tuning characteristic of the frequency fine-tuning circuit 500 of FIG. 5, when the second tuning voltage is maintained at (Vtune+Vdc)/2.

Referring to FIG. 8, the first tuning voltage Vtune ranges from about 1.0 V to about 3.0 V, and the effective capacitance for the two series-coupled AMOS varactors 510 and 520 ranges from about 75 fF to about 115 fF based on the tuning voltage. Referring back to FIG. 4, when one AMOS varactor is used, the tuning voltage Vtune ranges from about 1.0 V to about 2.0 V, and the capacitance ranges about from 140 fF to about 590 fF based on the tuning voltage.

When the two series-coupled AMOS varactors are used as in FIGS. 5, 6, and 7, the range of the tuning voltage is doubled with a smaller range of the capacitance. In other words, the gain change of the VCO including the frequency fine-tuning circuit 500 in FIG. 5 is substantially decreased from the case in which just one AMOS varactor is used.

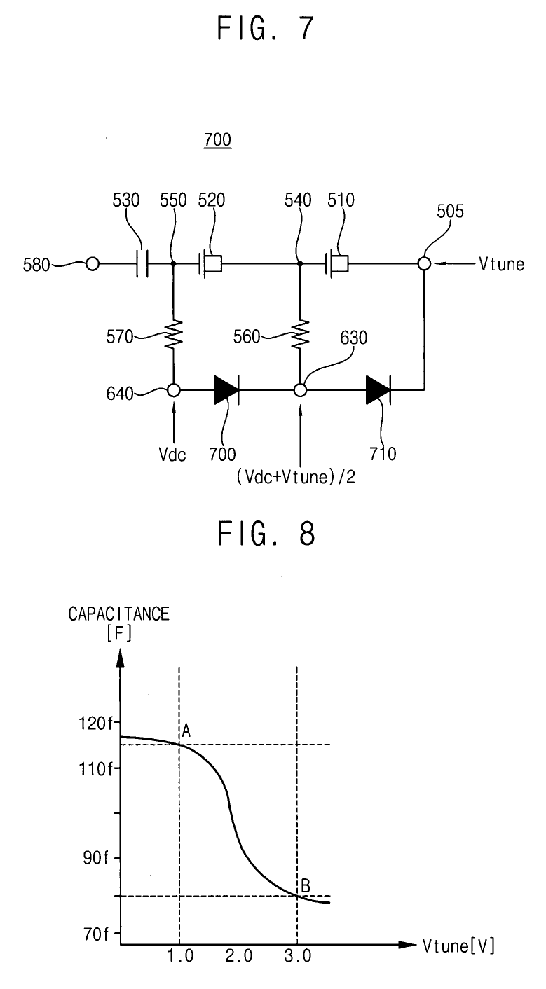

FIGS. 6 and 7 illustrate example embodiments for maintaining the second tuning voltage at (Vtune+Vdc)/2. Elements having the same reference number in FIGS. 5, 6, and 7 refer to elements having similar structure and/or function.

FIG. 6 shows a frequency fine-tuning circuit 600 that uses division resistors 610 and 620 for maintaining the second tuning voltage at (Vtune+Vdc)/2. Referring to FIG. 6, a first division resistor 610 is coupled between the tuning node 505 and the third node 630. A second division resistor 620 is coupled between the third node 630 and the fourth node 640.

A voltage difference between the bias voltage Vdc and the tuning voltage Vtune (Vdc−Vtune) is divided across the first and second division resistors 610 and 620 to provide the second tuning voltage at the first node 540. The bias voltage (Vdc) is a fixed voltage in one embodiment of the present invention. In an example embodiment of the present invention, the resistances of the first and second division resistors 610 and 620 are substantially the same.

In that case, the second tuning voltage generated at the third node 630 and at the first node 540 is maintained at the average of the first tuning voltage Vtune and the bias voltage Vdc, (i.e., (Vtune+Vdc)/2). In one embodiment of the present invention, the first tuning voltage Vtune ranges from a ground voltage to the bias voltage Vdc. In that case, the second tuning voltage generated at the third node 630 and at the first node 540 ranges from a half of the bias voltage Vdc/2 to the bias voltage Vdc.

FIG. 7 shows a frequency fine-tuning circuit 700 that uses turned-on diodes 710 and 700 for maintaining the second tuning voltage at (Vtune+Vdc)/2. Referring to FIG. 7, a first turned-on diode 710 is coupled between the tuning node 505 and the third node 630. A second turned-on diode 700 is coupled between the third node 630 and the fourth node 640.

The bias voltage Vdc is higher than the first tuning voltage Vtune such that the first and second turned-on diodes 710 and 700 are forward biased and turned on to act as resistors. In one embodiment of the present invention, the resistances of the first and second turned-on diodes 710 and 700 are-substantially the same. In that case, the second tuning voltage generated at the third node 630 and at the first node 540 is maintained at the average of the first tuning voltage Vtune and the bias voltage Vdc, (i.e., (Vtune+Vdc)/2).

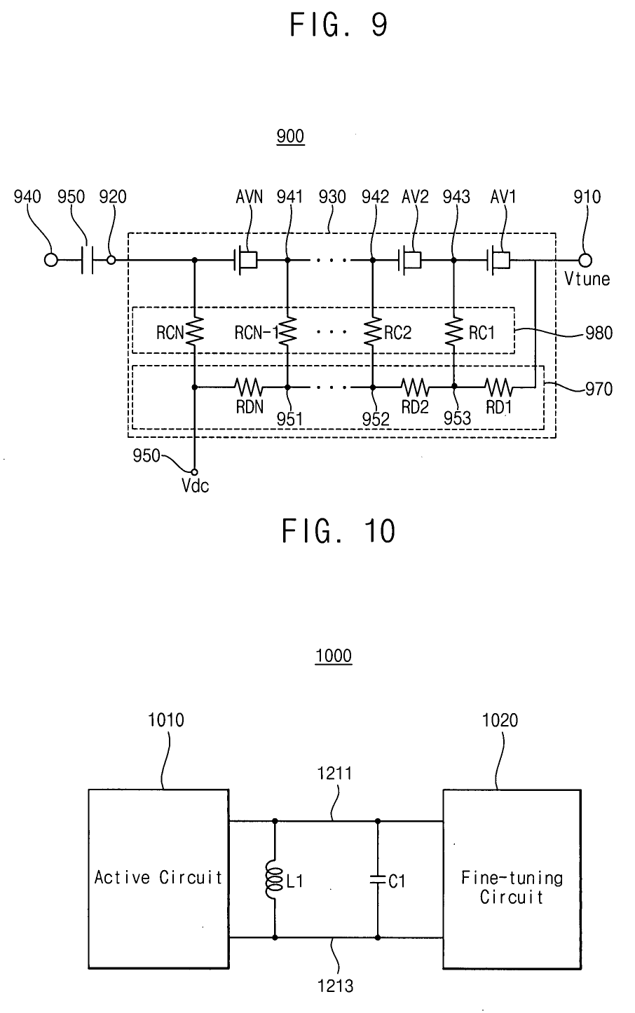

FIG. 9 is a circuit diagram of a frequency fine-tuning circuit 900 generalized to include at least three series-coupled varactor AV1, AV2, . . . , and AVN according to another example embodiment of the present invention. Referring to FIG. 9, the frequency fine-tuning circuit 900 includes a tuning node 910, a bias node 920, and a varactor array 930. A tuning voltage (Vtune) is applied on the tuning node 910. A bias voltage (Vdc) is applied on a bias application node 950 and thus the bias node 920.

The frequency fine-tuning circuit 900 also includes a blocking capacitor 950 coupled between the bias node 920 and an oscillating node 940. The blocking capacitor 950 may be implemented with a MIM (metal-insulator-metal) capacitor that prevents DC noise from being transferred to the bias node. 920.

The varactor unit 930 includes the N AMOS varactors AV1, AV2, . . . , and AVN coupled in series between the bias node 920 and the tuning node 910, with N being an integer greater than 2. The varactor unit 930 also includes a voltage divider unit 970 with N division resistors RD1, RD2, . . . , and RDN coupled in series between the bias application node 950 and the tuning node 910. The varactor unit 930 further includes a voltage coupling unit 980 with N coupling resistors RC1, RC2, . . . , and RCN.

Each of the coupling resistors RC1, RC2, . . . , and RCN is coupled between a respective node of the series-coupled division resistors RD1, RD2, . . . , and RDN and a respective node of the series-coupled AMOS varactors AV1, AV2, . . . , and AVN. A voltage difference between the bias voltage Vdc and the tuning voltage Vtune (Vdc−Vtune) is divided along the series-coupled division resistors RD1, RD2, . . . , and RDN. Such voltages are coupled to the nodes of the series-coupled AMOS varactors AV1, AV2, . . . , and AVN via the coupling resistors RC1, RC2, . . . , and RCN.

Thus, the voltages applied at the nodes of the series-coupled AMOS varactors AV1, AV2, . . . , and AVN successively increases from the tuning node 910 to the bias node 920. In one embodiment of the present invention, the resistances of the division resistors RD1, RD2, . . . , and RDN are substantially the same, and the resistances of the coupling resistors RC1, RC2, . . . , and RCN are substantially the same. A linearity of the frequency fine-tuning circuit 900 is increased as the number N of the AMOS varactors AV1, AV2, . . . , and AVN is increased.

FIG. 10 is a block diagram of a VCO (voltage controlled oscillator) 1000 including a fine-tuning circuit according to an example embodiment of the present invention. Referring to FIG. 10, the VCO 1000 includes an active circuit 1010 having first and second oscillating nodes 1211 and 1213, an inductor L1 and a capacitor C1 coupled in parallel between the first and second oscillating nodes 1211 and 1213, and a frequency fine-tuning circuit 1020 coupled to the oscillating nodes 1211 and 1213.

The VCO 1000 is an LC oscillator with an oscillating frequency of the VCO being determined by a resonance of the inductance of the inductor L1, the capacitance of the capacitor C1, and an equivalent capacitance of the frequency fine-tuning circuit 1020. The frequency fine-tuning circuit 1020 is implemented with any of the frequency fine-tuning circuit 600 of FIG. 6 or the frequency fine-tuning circuit 700 of FIG. 7.

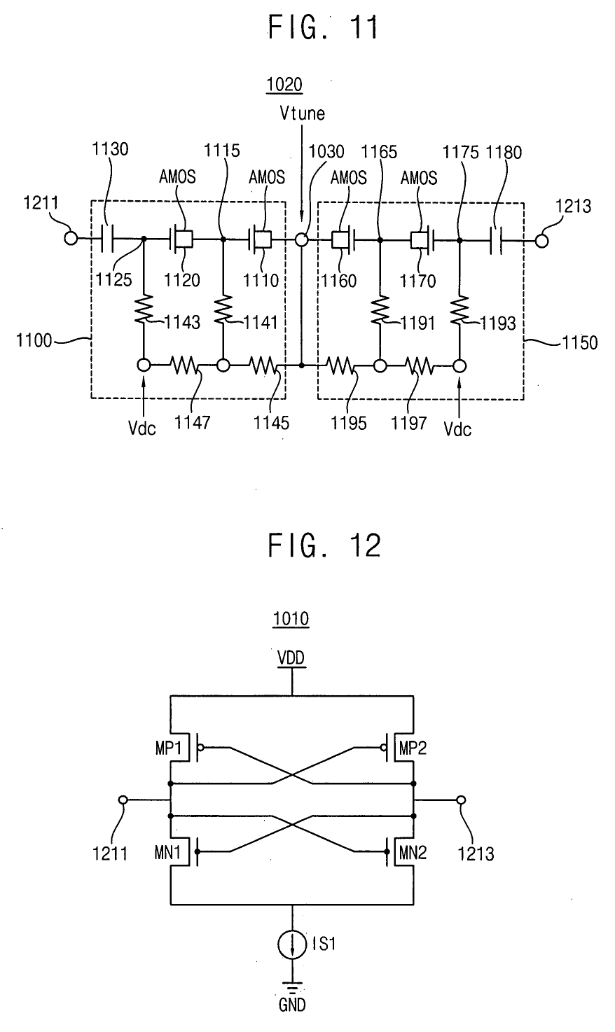

The frequency fine-tuning circuit 1020 includes two frequency fine-tuning circuits that are coupled symmetrically as illustrated by an example of FIG. 11. Referring to FIG. 11, the fine-tuning circuit 1020 includes a first varactor unit 1100 and a second varactor unit 1150 that are coupled symmetrically with each other about a tuning node 1030 between the first and second oscillating node 1211 and 1213. FIG. 11 illustrates an example with each of the first varactor unit 1100 and the second varactor unit 1150 being implemented similarly as the frequency fine-tuning circuit of FIG. 6.

The first varactor unit 1100 includes a first AMOS varactor 1110, a second AMOS varactor 1120, and a blocking capacitor 1130. A coupled source and drain terminal of the first AMOS varactor 1110 is coupled to the tuning node 1030. A coupled source and drain terminal of the second AMOS varactor 1120 is coupled to a gate terminal of the first AMOS varactor 1110 at a node 1115. A gate terminal of the second AMOS varactor 1120 is coupled to a first terminal of the blocking capacitor 1130 at a node 1125. A second terminal of the blocking capacitor 1130 is coupled to the first oscillating node 1211.

A tuning voltage (Vtune) is applied on the tuning node 1030, and a bias voltage (Vdc) is applied on the node 1125 through a resistor 1143. Another resistor 1141 is coupled between the node 1115 and another node between division resistor 1145 and 1147. The resistances of the resistors 1141 and 1143 are substantially the same in an embodiment of the present invention.

A voltage difference Vdc−Vtune is applied across the division resistor 1145 and 1147 coupled in series. The resistances of the division resistors 1145 and 1147 are substantially the same in an embodiment of the present invention. In that case, a voltage applied on the node 1115 through the resistor 1141 is maintained at an average of the tuning voltage and the bias voltage, (i.e., (Vtune+Vdc)/2). The tuning voltage Vtune ranges from a ground voltage to the bias voltage Vdc in an embodiment of the present invention.

The second varactor unit 1150 includes a third AMOS varactor 1160, a fourth AMOS varactor 1170, and a blocking capacitor 1180. A coupled source and drain terminal of the third AMOS varactor 1160 is coupled to the tuning node 1030. A coupled source and drain terminal of the fourth AMOS varactor 1170 is coupled to a gate terminal of the third AMOS varactor 1160 at a node 1165. A gate terminal of the fourth AMOS varactor 1170 is coupled to a first terminal of the blocking capacitor 1180 at a node 1175. A second terminal of the blocking capacitor 1180 is coupled to the second oscillating node 1213.

The tuning voltage (Vtune) is applied on the tuning node 1030, and the bias voltage (Vdc) is applied on the node 1175 through a resistor 1193. Another resistor 1191 is coupled between the node 1165 and a node between division resistor 1195 and 1197. The resistances of the resistors 1191 and 1193 are substantially the same in one embodiment of the present invention.

In addition, the resistances of the division resistors 1195 and 1197 are substantially the same in one embodiment of the present invention. In that case, a voltage applied on the node 1165 through the resistor 1191 is maintained at the average of the tuning voltage and the bias voltage, (i.e., (Vtune+Vdc)/2). The tuning voltage Vtune ranges from a ground voltage to the bias voltage Vdc, in one embodiment of the present invention.

FIG. 12 is a circuit diagram of an example active circuit 1010 of FIG. 10. Referring to FIG. 12, the active circuit 1010 includes PMOSFETs (P-channel metal oxide semiconductor field effect transistors) MP1 and MP2 that are latch-coupled, NMOSFETs (N-channel metal oxide semiconductor field effect transistors) that are latch-coupled, and a current source IS1.

The PMOSFET MP1 has a source coupled to a power supply voltage VDD, a gate coupled to the second oscillating node 1213, and a drain coupled to the first oscillating node 1211. The PMOSFET MP2 has a source coupled to the power supply voltage VDD, a gate coupled to the first oscillating node 1211, and a drain coupled to the second oscillating node 1213.

The NMOSFET MN1 has a drain coupled to the first oscillating node 1211, a gate coupled to the second oscillating node 1213, and a source coupled to the current source IS1. The NMOSFET MN2 has a drain coupled to the second oscillating node 1213, a gate coupled to the first oscillating node 1211, and a source coupled to the current source IS1. The current source IS1 is coupled to the sources of the transistors MN1 and MN2 and the ground node. The active circuit 1010 latches voltages of the first and second oscillating nodes 1211 and 1213.

In this manner, the VCO 1000 including such a frequency fine-tuning circuit 1020 has wider tuning range due to increased linearity. Accordingly, the VCO 1000 provide a more stable oscillating frequency.

The foregoing is by way of example only and is not intended to be limiting. For example, any numbers or number of elements described and illustrated herein is by way of example only. In addition, the present invention may be practiced with other types of devices such as other types of varactors aside from the example AMOS varactors.

The present invention is limited only as defined in the following claims and equivalents thereof.

What is claimed is:

1. A frequency fine-tuning circuit comprising:
a first varactor coupled between a tuning node with a first tuning voltage applied thereon and a first node with a second tuning voltage applied thereon; and
a second varactor coupled between the first node and a second node with a bias voltage applied thereon,
wherein the second tuning voltage is in a range between the first tuning voltage and the bias voltage.

2. The frequency fine-tuning circuit of claim 1, wherein the second tuning voltage is less than the bias voltage and greater than the first tuning voltage.

3. The frequency fine-tuning circuit of claim 2, wherein the second tuning voltage is an average of the first tuning voltage and the bias voltage.

4. The frequency fine-tuning circuit of claim 1, further comprising:
a blocking capacitor, coupled between the second node and an oscillating node, for preventing DC noise from being transferred to the second node.

5. The frequency fine-tuning circuit of claim 4, wherein the blocking capacitor is a metal-insulator-metal (MIM) capacitor.

6. The frequency fine-tuning circuit of claim 1, wherein the first varactor is a first AMOS (accumulation metal-oxide semiconductor) varactor having a first coupled source and drain terminal connected to the tuning node and having a first gate terminal connected to the first node, and wherein the second varactor is a second AMOS (accumulation metal-oxide semiconductor) varactor having a second coupled source and drain terminal connected to the first node and having a second gate terminal connected to the second node.

7. The frequency fine-tuning circuit of claim 1, wherein the first tuning voltage is in a range of a ground voltage to the bias voltage.

8. The frequency fine-tuning circuit of claim 1, further comprising:
a first resistor coupled between the first node and a third node having the second tuning voltage applied thereon; and
a second resistor coupled between the second node and a fourth node having the bias voltage applied thereon.

9. The frequency fine-tuning circuit of claim 8, wherein resistances of the first and second resistors are substantially same.

10. The frequency fine-tuning circuit of claim 8, further comprising:
a first division resistor coupled between the tuning node and the third node; and
a second division resistor coupled between the third node and the fourth node.

11. The frequency fine-tuning circuit of claim 10, wherein resistances of the first and second division resistors are substantially same.

12. The frequency fine-tuning circuit of claim 10, wherein the first and second division resistors are turned-on diodes.

13. The frequency fine-tuning circuit of claim 1, further comprising:
at least one additional varactor coupled in series with the first and second varactors, with nodes between the varactors of the series varying between the tuning voltage and the bias voltage.

14. The frequency fine-tuning circuit of claim 13, further comprising:
a series of division resistors coupled between the tuning node and a node having the bias voltage applied thereon, wherein a respective one of the nodes between the varactors is coupled via a respective resistor to a respective one of a plurality of nodes between the division resistors.

15. A voltage-controlled oscillator (VCO) comprising:
an active circuit including first and second oscillating nodes;
an inductor coupled between the first and second oscillating nodes;
a capacitor coupled between the first and second oscillating nodes; and
a frequency fine-tuning circuit including at least one varactor unit each coupled to a respective one of the first and second oscillating nodes, each varactor unit including:
a first varactor coupled between a tuning node with a first tuning voltage applied thereon and a first node with a second tuning voltage applied thereon;
and
a second varactor coupled between the first node and a second node with a bias voltage applied thereon,
wherein the second tuning voltage is in a range between the first tuning voltage and the bias voltage, and wherein the second node is coupled to the respective one of the first and second oscillating nodes.

16. The VCO of claim 15, wherein the at least one varactor includes:
a first varactor unit having the first and second varactors with the second node being coupled to the first oscillating node; and
a second varactor unit including:
a third varactor coupled between the tuning node with the first tuning voltage applied thereon and a third node with a third tuning voltage applied thereon; and
a fourth varactor coupled between the third node and a fourth node with the bias voltage applied thereon,
wherein the fourth tuning voltage is in a range between the first tuning voltage and the bias voltage, and wherein the fourth node is coupled to the second oscillating node.

17. The VCO of claim 16, further comprising:
a first blocking capacitor coupled between the first oscillating node and the second node; and
a second blocking capacitor coupled between the second oscillating node and the fourth node.

18. The VCO of claim 15, wherein the first tuning voltage ranges from a ground voltage to the bias voltage.

19. The VCO of claim 15, wherein each of the first, second, third, and fourth varactors is a respective AMOS (accumulation metal oxide semiconductor) varactor.

20. The VCO of claim 15, wherein the active circuit includes:
at least one pair of MOSFETs (metal oxide semiconductor field effect transistors) latch-coupled between the first and second oscillating nodes.
